(19) United States
(12) Patent Application Publication
(10) Pub. No.: US 2025/0019569 A1
(43) Pub. Date: Jan. 16, 2025

(54) POLISHING COMPOSITIONS AND METHODS OF USE THEREOF

(71) Applicant: Fujifilm Electronic Materials U.S.A., Inc., N. Kingstown, RI (US)

(72) Inventors: Eric Turner, Phoenix, AZ (US); Bin Hu, Chandler, AZ (US); Alexei P. Leonov, Chandler, AZ (US)

(21) Appl. No.: 18/766,908

(22) Filed: Jul. 9, 2024

Related U.S. Application Data
(60) Provisional application No. 63/526,709, filed on Jul. 14, 2023.

(51) Int. Cl. C09G 1/02; C09K 3/14; H01L 21/3105

(52) U.S. Cl. CPC C09G 1/02; C09K 3/1409; H01L 21/31053

(57) ABSTRACT

This disclosure relates to polishing compositions containing at least one abrasive, at least one polymer removal enhancer, and at least one solvent. The polishing compositions of this disclosure may optionally include at least one of a cationic surfactant, an azole-containing corrosion inhibitor, or a nonionic surfactant. The polishing compositions of this disclosure may polish a polymeric substrate at a rate of at least about 200 Å/min.

### CROSS-REFERENCE TO RELATED APPLICATION

The present application claims priority to U.S. Provisional Application Ser. No. 63/526,709, filed on Jul. 14, 2023, the contents of which are hereby incorporated by reference in their entirety.

### BACKGROUND

The semiconductor industry is continually driven to improve chip performance by further miniaturization of devices through process and integration innovations. Chemical Mechanical Polishing/Planarization (CMP) is a powerful technology as it makes many complex integration schemes at the transistor level possible, thereby facilitating increased chip density.

CMP is a process used to planarize/flatten a wafer surface by removing material using abrasion-based physical processes concurrently with surface-based chemical reactions. In general, a CMP process involves applying a CMP slurry (e.g., an aqueous chemical formulation) to a wafer surface while contacting the wafer surface with a polishing pad and moving the polishing pad in relation to the wafer. Slurries typically include an abrasive component and dissolved chemical components, which can vary significantly depending upon the materials present on the wafer surface that will be interacting with the slurry and the polishing pad during the CMP process.

CMP is commonly applied to a variety of surfaces including metals, metal oxides, metal nitrides, and dielectric materials such as silicon oxide and silicon nitride. However, the need to polish polymeric packaging materials has become a recent challenge due to changes in chip designs and architectures. Polymer packaging in the semiconductor industry refers to the use of polymer-based materials to provide reliable protection, support, and electrical connection for semiconductor devices. Polymer packaging materials have advantages such as low cost, easy processability, and tunable properties over metal-based or ceramic-based materials. Polymer packaging materials include molding compounds, thermal interface materials, underfills, die attach materials, and substrates. These materials are often modified with nanofillers or dopants to enhance their performance in terms of thermal conductivity, dielectric constant, dielectric loss, glass transition temperature, coefficient of thermal expansion, viscosity, and processability. Polymer packaging materials play a critical role in the development of semiconductor devices for various applications such as consumer electronics, data centers, automotive, medical devices, Internet of Things, artificial intelligence, power electronics and more.

Chemical mechanical polishing (CMP) is finding increased use for advanced polymer packaging in some applications. CMP is important for wafer-level packaging, especially for hybrid bonding, which requires ultra-flat and clean surfaces for direct metal-to-metal bonding. CMP is also used for planarizing interlayer dielectrics (ILD), which are often made of polymer-based materials with low dielectric constants. CMP can help reduce defects such as surface scratches, prepare a uniform surface for further processing, and otherwise improve the performance of the devices.

Many currently available CMP slurries were specifically designed to remove materials more common in older chip designs and do not perform well when polishing polymeric materials used in advanced packaging applications.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

As defined herein, unless otherwise noted, all percentages expressed should be understood to be percentages by weight to the total weight of the chemical mechanical polishing composition.

In one aspect, this disclosure features a polishing composition that includes (1) at least one abrasive; (2) at least one polymer removal enhancer having the following formula:

X₄P⁺N⁻,

wherein each X, independently, is a substituted or unsubstituted C₁-C₈ alkyl group, a substituted or unsubstituted C₂-C₈ alkenyl group, a substituted or unsubstituted cycloalkyl group, or a substituted or unsubstituted aryl group, provided that at most three X groups are unsubstituted methyl; P⁺ is an ammonium cation or phosphonium cation; and N⁻ is a sulfate anion, halide anion, or hydroxide anion; and (3) at least one solvent.

In another aspect, this disclosure features a method of polishing a substrate, the method including the steps of: applying a polishing composition described herein to a surface of a substrate, wherein the surface contains a polymer; and bringing a pad into contact with the surface of the substrate and moving the pad in relation to the substrate.

Other aspects and advantages of the claimed subject matter will be apparent from the following description and the appended claims.

### DETAILED DESCRIPTION

Embodiments disclosed herein relate generally to compositions and methods of using said compositions to polish semiconductor substrates (e.g., wafers) that include at least a polymeric portion. For example, the polymeric portion of the semiconductor substrate may be used for packaging purposes on the semiconductor substrate. In some embodiments, it is desirable to remove the polymeric material at a high removal rate (e.g., greater than about 750 Å/min). The present inventors have surprisingly discovered that the compositions disclosed herein can efficiently remove polymeric materials at a high rate while producing a smooth surface amenable for further processing steps.

In one or more embodiments, the polishing composition described herein includes at least one abrasive, at least one polymer removal enhancer, and at least one solvent.

In one or more embodiments, a polishing composition according to the present disclosure can include from about 0.1% to about 50% by weight abrasive, from about 0.01% to about 15% by weight polymer removal enhancer, and from about 20% to about 99.9% by weight solvent (e.g., deionized water). Optionally, the polishing composition described herein can further include at least one cationic surfactant in an amount of from about 0.0001% to about 10% by weight of the composition.

In one or more embodiments, the present disclosure provides a concentrated polishing composition that can be diluted with water prior to use by up to a factor of two, or up to a factor of four, or up to a factor of six, or up to a factor of eight, or up to a factor of ten. In other embodiments, the present disclosure provides a point-of-use (POU) polishing composition containing the above-described polishing composition and optionally an oxidizer for use on a substrate.

In one or more embodiments, a POU polishing composition can include from about 0.1% to about 12% by weight abrasive, from about 0.01% to about 1.5% by weight polymer removal enhancer, optionally from about 0.1% to about 5% by weight oxidizer, and from about 82% to about 99% by weight solvent (e.g., deionized water). Further, the POU polishing composition described herein can optionally further include at least one cationic surfactant in an amount of from about 0.0001% to about 5% by weight of the composition.

In one or more embodiments, a concentrated polishing composition can include from about 1% to about 50% by weight abrasive, from about 1% to about 15% by weight polymer removal enhancer, and from about 35% to about 98% by weight solvent (e.g., deionized water). Optionally, the concentrated polishing composition described herein can further include at least one cationic surfactant in an amount of from about 0.001% to about 10% by weight of the composition.

In one or more embodiments, the polishing composition described herein can include at least one (e.g., two or three) abrasive. In one or more embodiments, the polishing composition can include a single type of abrasive (e.g., not a composite abrasive or multiple type of abrasives). In some embodiments, the at least one abrasive is selected from the group consisting of cationic abrasives, substantially neutral abrasives, and anionic abrasives. In one or more embodiments, the at least one abrasive is selected from the group consisting of alumina, silica, titania, ceria, zirconia, co-formed products thereof (i.e., co-formed products of alumina, silica, titania, ceria, or zirconia), coated abrasives, surface modified abrasives, and mixtures thereof. In some embodiments, the at least one abrasive does not include ceria or an abrasive surface modified by a Si-containing compound. In some embodiments, the at least one abrasive is of high-purity, and can have less than about 100 ppm of alcohol, less than about 100 ppm of ammonia, and/or less than about 100 parts per billion (ppb) of an alkali cation such as sodium cation.

In some embodiments, the at least one abrasive is in an amount of from at least about 0.1% (e.g., at least about 0.5%, at least about 1%, at least about 2%, at least about 4%, at least about 5%, at least about 10%, at least about 12%, at least about 15%, or at least about 20%) by weight to at most about 50% (e.g., at most about 45%, at most about 40%, at most about 35%, at most about 30%, at most about 25%, at most about 20%, at most about 15%, at most about 12%, at most about 10%, or at most about 5%) by weight of the polishing composition described herein.

In one or more embodiments, the at least one abrasive can have a mean particle size (MPS) of from at least about 1 nm (e.g., at least about 5 nm, at least about 10 nm, at least about 20 nm, at least about 40 nm, at least about 50 nm, at least about 60 nm, at least about 80 nm, at least about 100 nm, or at least about 150 nm, or at least about 180 nm, or at least about 200 nm) to at most about 1000 nm (e.g., at most about 800 nm, at most about 600 nm, at most about 500 nm, at most about 400 nm, at most about 200 nm, at most about 150 nm, or at most about 100 nm). Without wishing to be bound by theory, an abrasive having an MPS of at least about 180 nm can surprisingly have a significant increase in polishing rate of a polymeric material, while not detrimentally increasing defects or non-uniformity of the polished surface. As used herein, the MPS is determined by dynamic light scattering techniques.

In one or more embodiments, the polishing composition described herein can include at least one (e.g., two or three) polymer removal enhancer. In one or more embodiments, the polishing composition includes a single polymer removal enhancer or at most two polymer removal enhancers. In one or more embodiments, the at least one polymer removal enhancer is of formula (I): X₄P⁺N⁻ (I), wherein each X, independently, is a substituted or unsubstituted C₁-C₈ alkyl group, a substituted or unsubstituted C₂-C₈ alkenyl group, a substituted or unsubstituted cycloalkyl group, or a substituted or unsubstituted aryl group, provided that at most three (e.g., at most two or at most one) X groups are unsubstituted methyl; P⁺ is an ammonium cation or phosphonium cation; and N⁻ is a sulfate anion, halide anion, or hydroxide anion.

In one or more embodiments, substituents on alkyl, alkenyl, cycloalkyl, and aryl include, but are not limited to, C₁-C₁₀ alkyl, C₂-C₁₀ alkenyl, C₂-C₁₀ alkynyl, C₃-C₂₀ cycloalkyl, C₃-C₂₀ cycloalkenyl, C₃-C₂₀ heterocycloalkyl, C₃-C₂₀ heterocycloalkenyl, C₁-C₁₀ alkoxy, aryl, aryloxy, heteroaryl, heteroaryloxy, amino, C₁-C₁₀ alkylamino, C₁-C₂₀ dialkylamino, arylamino, diarylamino, hydroxyl, halogen, thio, C₁-C₁₀ alkylthio, arylthio, C₁-C₁₀ alkylsulfonyl, arylsulfonyl, acylamino, aminoacyl, aminothioacyl, amidino, guanidine, ureido, cyano, nitro, acyl, thioacyl, acyloxy, carboxyl, and carboxylic ester.

In one or more embodiments, the polymer removal enhancer is a tetraalkylammonium hydroxide of formula (II): (CH₃(CH₂)ₓ)₄N(OH) (II), wherein each x, independently, is 0, 1, 2, 3, 4, 5, 6, or 7, provided that the tetraalkylammonium hydroxide of formula (II) is not tetramethylammonium hydroxide. In one or more embodiments, the polymer removal enhancer is selected from the group consisting of tetrapropylammonium hydroxide, tetrabutylammonium hydroxide, tetraethylammonium hydroxide, tris(2-hydroxyethyl)methylammonium hydroxide, diallyldimethylammonium chloride, tetrakis(hydroxymethyl)phosphonium sulfate, tetraphenylphosphonium bromide, methyltrioctylammonium chloride, tetrabutylphosphonium hydroxide, hexamethonium hydroxide, benzyldimethylphenylammonium chloride, benzyltriethylammonium hydroxide, tetrahexylammonium hydroxide, and mixtures thereof.

In one or more embodiments, the at least one polymer removal enhancer is in an amount of from about 0.01% to about 15% by weight of the composition. For example, the at least one polymer removal enhancer can be from at least about 0.01% (e.g., at least about 0.05%, at least about 0.1%, at least about 0.25%, at least about 0.5%, at least about 1%, at least about 1.5%, or at least about 2%) by weight to at most about 15% (e.g., at most about 12.5%, at most about 10%, at most about 7.5%, at most about 5%, at most about 2.5%, at most about 1%, or at most about 0.5%) by weight of the polishing composition described herein. Without wishing to be bound by theory, the inventors have surprisingly discovered that the at least one polymer removal enhancer can significantly increase the polishing rate of a polymeric material (e.g., when compared against compounds that do not meet the requirements of the formula (I) above).

In one or more embodiments, the polishing composition described herein can optionally further include at least one (e.g., two or three) surfactant. In one or more embodiments, the polishing composition described herein can include a single type of surfactant (e.g., a cationic surfactant). In one or more embodiments, the surfactant can be selected from the group consisting of primary fatty amines, secondary fatty amines, ethoxylated amines, ethoxylated ether amines, and cationic surfactants (e.g., those including an ammonium or a phosphonium cationic group). In one or more embodiments, the surfactant can include at least one (e.g., two, three, or four) alkyl group containing at least eight carbons (e.g., at least 10 carbons, at least 12 carbons, at least about 14 carbons, at least 16 carbons, at least 18 carbons, or at least 20 carbons) and/or at most 30 carbons. For example, the surfactant can be a tetraalkylammonium hydroxide containing at least one (e.g., two, three, or four) C₈-C₃₀ alkyl group and at least one (e.g., two, three, or four) C₁-C₈ alkyl group (e.g., a methyl group). In some embodiments, the surfactant can be a tetraalkylammonium hydroxide containing one C₈-C₃₀ alkyl group and three C₁-C₈ alkyl groups (e.g., three methyl groups). In one or more embodiments, the surfactant is selected from the group consisting of dodecylamine, dicocoalkylamine, tallow amine, bis-(2-hydroxyethyl) isodecyloxypropylamine, poly (5) oxyethylene isodecyloxproplamine, bis-(2-hydroxyethyl) isotridecyloxypropylamine, poly (5) oxyethylene isotridecyloxypropylamine, bis-(2-hydroxyethyl) tallow amine, N-tallow-poly (3) oxyethylene-1,3-diaminopropane, bis-(2-hydroxyethyl) cocoalkyloxypropylamine, poly bis-(2-hydroxyethyl) oxyethylene cocoalkyloxypropylamine, octyltrimethylammonium hydroxide, decyltrimethylammonium hydroxide, dodecyltrimethylammonium hydroxide, tetradecyltrimethylammonium hydroxide, hexadecyltrimethylammonium hydroxide, octadecylammonium hydroxide, cicosyltrimethylammonium hydroxide, and mixtures thereof. In one or more embodiments, the surfactant is chemically distinct from the polymer removal enhancer. Without wishing to be bound by theory, the inventors surprisingly discovered that the cationic surfactant has a synergistic relationship with the polymer removal enhancer that produces a much higher polymer removal rate than the removal rate observed when each are used on their own.

In one or more embodiments, the at least one cationic surfactant can be from at least about 0.0001% (e.g., at least about 0.0005%, at least about 0.001%, at least about 0.005%, at least about 0.01%, at least about 0.05%, at least about 0.1%, at least about 0.5%, at least about 1%, at least about 2%, at least about 2.5%, or at least about 3%) by weight to at most about 10% (e.g., at most about 8%, at most about 6%, at most about 5%, at most about 4%, at most about 2%, or at most about 1%) by weight of the polishing composition described herein.

In one or more embodiments, the polishing composition described herein can optionally further include at least one (e.g., two or three) azole-containing corrosion inhibitor. In some embodiments, the at least one azole compound is selected from the group consisting of substituted or unsubstituted triazoles, substituted or unsubstituted tetrazoles, substituted or unsubstituted benzotriazoles, substituted or unsubstituted pyrazoles, substituted or unsubstituted imidazoles, substituted or unsubstituted benzimidazoles, substituted or unsubstituted thiadiazoles, substituted or unsubstituted thiabendazole, substituted or unsubstituted adenines, substituted or unsubstituted xanthines, and substituted or unsubstituted guanines. In one or more embodiments, the azole compound can be selected from the group consisting of 1,2,4-triazole, 1,2,3-triazole, tetrazole, benzotriazole, tolyltriazole, methyl benzotriazole (e.g., 1-methyl benzotriazole, 4-methyl benzotriazole, or 5-methyl benzotriazole), ethyl benzotriazole (e.g., 1-ethyl benzotriazole), propyl benzotriazole (e.g., 1-propyl benzotriazole), butyl benzotriazole (e.g., 1-butyl benzotriazole or 5-butyl benzotriazole), pentyl benzotriazole (e.g., 1-pentyl benzotriazole), hexyl benzotriazole (e.g., 1-hexyl benzotriazole or 5-hexyl benzotriazole), dimethyl benzotriazole (e.g., 5,6-dimethyl benzotriazole), chloro benzotriazole (e.g., 5-chloro benzotriazole), dichloro benzotriazole (e.g., 5,6-dichloro benzotriazole), chloromethyl benzotriazole (e.g., 1-(chloromethyl)-1-H-benzotriazole), chloroethyl benzotriazole, phenyl benzotriazole, benzyl benzotriazole, aminotriazole, aminobenzimidazole, aminotetrazole, pyrazole, imidazole, adenine, xanthine, guanine, benzimidazole, thiabendazole, 1-hydroxybenzotriazole, 2-methylbenzothiazole, 2-aminobenzimidazole, 2-amino-5-ethyl-1,3,4-thiadiazole, 3,5-diamino-1,2,4-triazole, 3-amino-5-methylpyrazole, 4-amino-4H-1,2,4-triazole, and mixtures thereof. In one or more embodiments, when at least one azole-containing corrosion inhibitor is included in the polishing composition a cationic surfactant is not included in the polishing composition. Without wishing to be bound by theory, it is believed that an azole compound (such as those described above) can significantly reduce or minimize the corrosion of metals (e.g., copper or tin) that may be included in a semiconductor substrate.

In some embodiments, the azole-containing corrosion inhibitor is in an amount of from at least about 0.0001% (e.g., at least about 0.0002%, at least about 0.0005%, at least about 0.001%, at least about 0.002%, at least about 0.005%, at least about 0.01%, at least about 0.02%, at least about 0.05%, at least about 0.1%, at least about 0.2%, or at least about 0.5%) by weight to at most about 1% (e.g., at most about 0.8%, at most about 0.6%, at most about 0.5%, at most about 0.4%, at most about 0.2%, at most about 0.1%, at most about 0.05%, at most about 0.02%, at most about 0.01%, or at most about 0.005%) by weight of the polishing composition described herein.

In one or more embodiments, the polishing composition described herein can optionally further include at least one nonionic surfactant. In one or more embodiments, the nonionic surfactant can include a polyalkylene oxide alkyl phenyl ether-based surfactant; an alcohol alkoxylate (polyalkylene oxide alkyl ether)-based surfactant; a block polymer-based surfactant composed of polyethylene oxide and polypropylene oxide; a polyoxyalkylene distyrenated phenyl ether-based surfactant; a polyalkylene tribenzyl phenyl ether-based surfactant; an acetylene polyalkylene oxide-based surfactant; a polyoxyethylene sorbitol fatty acid ester-based surfactant; and a polyoxyethylene alkylamine-based surfactant. Among the above nonionic surfactants, alcohol alkoxylate is preferable. The alcohol alkoxylate is preferably the compound represented by General Formula (b) below.

R-L₁-(L²O)ₙ—H (b)

In General Formula (b), R represents an alkyl group. L¹ represents a single bond, an oxygen atom, or an alkylene group that may have an oxygen atom. L² represents an alkylene group having two or three carbon atoms. A plurality of L² groups may be identical to or different from one another. n represents a number of two or more. In General Formula (b) above, the number of carbon atoms included in the alkyl group represented by R is preferably 5 to 25, is more preferably 8 to 20, and is further preferably 10 to 18. The above alkyl group may be either linear or branched. The number of carbon atoms included in the alkylene group that may have an oxygen atom, which is represented by L′, is preferably 1 to 20, is more preferably 1 to 10, and is further preferably 1 to 5. n is preferably 3 to 50, is more preferably 4 to 30, and is further preferably 6 to 20. Examples of the alkylene group that may have an oxygen atom include —O—CH₂—CH₂— and —O—CH₂—CH₂—CH₂—. In one or more embodiments, when at least one nonionic surfactant is included in the polishing composition a cationic surfactant is not included in the polishing composition. Without wishing to be bound by theory, it is believed that a nonionic surfactant (such as those described above) can significantly reduce or minimize the corrosion of metals (e.g., copper or tin) that may be included in a semiconductor substrate.

In one or more embodiments, the hydrophile-lipophile balance (HLB) value of the nonionic surfactant is preferably 3 to 20, is more preferably 8 to 17, and is further preferably 8 to 15 in order to enhance the advantageous effects of the present invention. The HLB value is the value calculated using Griffin's formula (20×Mw/M, where Mw represents the molecular weight of a hydrophilic portion, and M represents the molecular weight of the nonionic surfactant). Depending on the situation, the catalog value or a value calculated using another method may be used. The closer to 20 the HLB value, the more hydrophilic the nonionic surfactant. The closer to 0 the HLB value, the more lipophilic the nonionic surfactant.

In one or more embodiments, the content of the nonionic surfactant is preferably 0.001% to 5.0% by mass, is more preferably 0.005% to 1.5% by mass, and is further preferably 0.01% to 1.2% by mass of the total mass of the polishing fluid in order to enhance the advantageous effects of the present invention. Only one type of the nonionic surfactant may be used alone. Alternatively, two or more types of the nonionic surfactants may be used. In the case where two or more types of the nonionic surfactants are used, it is preferable that the total content of the nonionic surfactants fall within the above range.

In one or more embodiments, the pH value of the polishing composition can range from at least about 7.5 (e.g., at least about 8, at least about 8.5, at least about 9, at least about 9.5, at least about 10, at least about 10.5, at least about 11, at least about 11.5, or at least about 12) to at most about 14 (e.g., at most about 13.5, at most about 13, at most about 12.5, at most about 12, at most about 11.5, at most about 11, at least about 10.5, at most about 10, at most about 9.5, at most about 9, at most about 8.5, or at most about 8).

In one or more embodiments, the polishing composition described herein can include a solvent (e.g., a primary solvent), such as water. In some embodiments, the solvent (e.g., water) is in an amount of from at least about 20% (e.g., at least about 25%, at least about 30%, at least about 35%, at least about 40%, at least about 45%, at least about 50%, at least about 55%, at least about 60%, at least about 65%, at least about 70%, at least about 75%, at least about 80%, at least about 85%, at least about 90%, at least about 92%, at least about 94%, at least about 95%, or at least about 97%) by weight to at most about 99.9% (e.g., at most about 99%, at most about 98%, at most about 96%, at most about 94%, at most about 92%, at most about 90%, at most about 85%, at most about 80%, at most about 75%, at most about 70%, or at most about 65%) by weight of the polishing composition described herein.

In one or more embodiments, the polishing composition described herein can optionally include an organic solvent as a secondary solvent. In one or more embodiments, the at least one organic solvent includes one or more solvents selected from the group consisting of methanol, ethanol, 1-propanol, 2-propanol, 1-butanol, 2-butanol, t-butyl alcohol, 1-pentanol, 2-pentanol, 3-pentanol, cyclohexanol, ethylene glycol, propylene glycol, 2-methoxyethanol, 2-ethoxyethanol, 2-propoxyethanol, 2-isopropoxyethanol, 2-butoxyethanol, propylene glycol methyl ether, propylene glycol propyl ether, diethylene glycol butyl ether, ethylene glycol dimethyl ether, ethylene glycol diethyl ether, acetone, acetonitrile, dimethyl sulfoxide, dimethylformamide, dimethylacetamide, tetrahydrofuran, 1-methyl-2-pyrrolidone, 3-methyl-2-oxazolidinone, N,N′-dimethylimidazolidinone, ethylene carbonate, propylene carbonate, glycerol, diethylene glycol, diglyme, dioxane, morpholine, butanone, 2-pentanone, 3-pentanone, monoethanolamine, 2-(2-aminoethoxy) ethanol, 2-amino-2-methyl-1,3-propanediol, 2-amino-2-hydroxymethyl-propane-1,3-diol, piperazine, 1-(2-hydroxyethyl) piperazine, and any mixtures thereof.

In some embodiments, the secondary solvent is in an amount of from at least about 0.0025% (e.g., at least about 0.005%, at least about 0.01%, at least about 0.02%, at least about 0.05%, at least about 0.1%, at least about 0.2%, at least about 0.4%, at least about 0.6%, at least about 0.8%, or at least about 1%) by weight to at most about 2% (e.g., at most about 1.8%, at most about 1.6%, at most about 1.5%, at most about 1.4%, at most about 1.2%, at most about 1%, at most about 0.8%, at most about 0.6%, at most about 0.5%, or at most about 0.1%) by weight of the polishing composition described herein.

In one or more embodiments, the polishing composition described herein can be substantially free of one or more of certain ingredients, such as organic solvents, pH adjusting agents (e.g., organic acids, inorganic acids, organic bases, or inorganic bases), tetramethylammonium hydroxide, alkali bases (such as alkali hydroxides), fluorine-containing compounds (e.g., fluoride compounds or fluorinated compounds (such as fluorinated polymers/surfactants)), zwitterionic compounds, ionic liquids, silicon-containing compounds such as silanes (e.g., alkoxysilanes), nitrogen containing compounds (e.g., amino acids, amines, aminoalcohols, or imines (e.g., amidines such as 1,8-diazabicyclo[5.4.0]-7-undecene (DBU) and 1,5-diazabicyclo[4.3.0]non-5-ene (DBN)), amides, or imides), salts (e.g., halide salts or metal salts), polymers (e.g., non-ionic, cationic, anionic, or water-soluble polymers), inorganic acids (e.g., hydrochloric acid, sulfuric acid, phosphoric acid, or nitric acid), surfactants (e.g., cationic surfactants, anionic surfactants, non-polymeric surfactants, biosurfactants, or non-ionic surfactants), plasticizers, oxidizing agents (e.g., hydrogen peroxide and periodic acid), corrosion inhibitors (e.g., azole or non-azole corrosion inhibitors), electrolytes (e.g., polyelectrolytes), and/or certain abrasives (e.g., polymeric abrasives, fumed silica, ceria abrasives, non-ionic abrasives, surface modified abrasives, negatively/positively charged abrasives, or ceramic abrasive composites). The halide salts that can be excluded from the polishing compositions include alkali metal halides (e.g., sodium halides or potassium halides) or ammonium halides (e.g., ammonium chloride), and can be fluorides, chlorides, bromides, or iodides. As used herein, an ingredient that is “substantially free” from a polishing composition refers to an ingredient that is not intentionally added into the polishing composition. In some embodiments, the polishing composition described herein can have at most about 1000 ppm (e.g., at most about 500 ppm, at most about 250 ppm, at most about 100 ppm, at most about 50 ppm, at most about 10 ppm, or at most about 1 ppm) of one or more of the above ingredients that are substantially free from the polishing composition. In some embodiments, the polishing compositions described herein can be completely free of one or more of the above ingredients.

The present disclosure also contemplates a method of using any of the above-described polishing compositions (e.g., concentrates or POU slurries). With the concentrate, the method can include the steps of diluting the concentrate to form a POU slurry (e.g., by a factor of at least two), and then contacting a substrate surface at least partially comprising a polymer with the POU slurry. In some embodiments, an oxidizer can be added to the polishing composition before, during, or after the dilution. With the POU polishing composition, the method can include the step of contacting the substrate surface at least partially comprising a polymer with the POU polishing composition.

In one or more embodiments, this disclosure features a polishing method that can include applying a polishing composition according to the present disclosure to a surface of a substrate in which the surface contains a polymer (e.g., a wafer having at least a polymer on the surface of the wafer); and bringing a pad into contact with the surface of the substrate and moving the pad in relation to the substrate. In one or more embodiments, the polymer on the surface of the substrate is selected from the group consisting of polyimides, acrylonitrile butadiene styrene (ABS), liquid crystal polymers, polyaryletherketone (PAEK), polyethylene terephthalate (PET), polyphenylene oxide (PPO), polyphenylene sulfide (PPS), polytetrafluoroethylene (PTFE), polybenzobisoxazole (PBO), benzocyclobutene-based polymers, and epoxy-based polymers. In one or more embodiments, the polymer on the substrate can be a composite material that includes the polymer and a secondary material (e.g., silica filler or other additives/dopants). In one or more embodiments, the polishing composition described herein can polish the polymer at a rate of from at least about 200 Å/min (e.g., at least about 500 Å/min, at least about 750 Å/min, at least about 1,000 Å/min, at least about 1,100 Å/min, at least about 1,200 Å/min, at least about 1,300 Å/min, at least about 1,400 Å/min, or at least about 1,500 Å/min) to at most about 50,000 Å/min (e.g., at most about 25,000 Å/min, at most about 10,000 Å/min, at most about 5,000 Å/min, at most about 2,500 Å/min, or at most about 1,500 Å/min). In one or more embodiments, the polymer removal rates above can be measured at 25° C. In one or more embodiments, the substrate may also include a metal (e.g., copper or tin) in addition to the polymer material described above.

Further, in some embodiments, after polishing a substrate with a polishing composition described herein, the polished substrate can undergo a rinse polishing process where a composition including all the components of the polishing composition described herein, except the abrasive, is applied to the polished substrate in the polishing tool and the pad of the polishing tool is brought into contact with the substrate and moved in relation to the substrate to create a rinse polished substrate. In some embodiments, after the polishing process and/or the rinse polishing process, the substrate can be removed from the polishing tool and subjected to a post-CMP cleaning in a cleaning tool (e.g., a brush scrubber or a spin rinse dryer).

In some embodiments, the method that uses a polishing composition described herein can further include producing a semiconductor device from the substrate treated by the polishing composition through one or more steps. For example, photolithography, ion implantation, dry/wet etching, plasma ashing, deposition (e.g., PVD, CVD, ALD, ECD), wafer mounting, die cutting, packaging, and testing can be used to produce a semiconductor device from the substrate treated by the polishing composition described herein.

The specific examples below are to be construed as merely illustrative, and not limitative of the remainder of the disclosure in any way whatsoever. Without further elaboration, it is believed that one skilled in the art can, based on the description herein, utilize the present invention to its fullest extent.

### Examples

The polishing removal rates described in Table 1 below were collected on blanket polyimide films. The polishing compositions used had a pH value from 9-11 and included only the components specified in Table 1 and deionized water as the primary solvent. The weight percent of the abrasive, polymer removal enhancer, and the cationic surfactant were kept constant throughout each example where they were used (e.g., Ex. 1 and Ex. 5 included the same weight percent abrasive and the same weight percent polymer removal enhancer).

TABLE 1

| | | | | Polyimide |
|---|---|---|---|---|
| | | Polymer Removal | Cationic | Removal Rate |
| | Abrasive | Enhancer | Surfactant | (Å/min) |
| Ex. 1 | Silica | KOH | No | 100 |
| | (MPS 150 nm) | | | |
| Ex. 2 | Silica | Alkylammonium | No | 300 |
| | (MPS 150 nm) | hydroxide | | |
| | | corresponding to | | |
| | | Formula (I) | | |
| Ex. 3 | Silica | Alkylammonium | No | 800 |
| | (MPS 150 nm) | hydroxide | | |
| | | corresponding to | | |
| | | Formula (I) | | |
| Ex. 4 | Silica | Alkylammonium | Yes | 1000 |
| | (MPS 150 nm) | hydroxide | | |
| | | corresponding to | | |
| | | Formula (II) | | |
| Ex. 5 | Silica | Alkylammonium | Yes | 1800 |
| | (MPS 200 nm) | hydroxide | | |
| | | corresponding to | | |
| | | Formula (II) | | |

The results in Table 1 show that the use of a polymer removal enhancer that is not according to either Formula (I) or Formula (II) resulted in unacceptably low polyimide removal rates as shown in Ex. 1. The polyimide removal rates were slightly increased by the substitution of a polymer removal enhancer according to Formula (I) as shown in Ex. 2. A significant increase in the polyimide removal rate is seen when the polymer removal enhancer was an alkylammonium hydroxide according to Formula (II) as shown in Ex. 3. In Ex. 4, a further increase in the polyimide removal rate was shown with the addition of a cationic surfactant described in the present application. Ex. 5 demonstrates that the use of a silica with a MPS larger than the prior examples greatly increased the polyimide removal rate.

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims.

What is claimed is:

1. A polishing composition, comprising:
at least one abrasive;
at least one polymer removal enhancer of formula (I):
X₄P⁺N⁻ (I),
wherein each X, independently, is a substituted or unsubstituted C₁-C₈ alkyl group, a substituted or unsubstituted C₂-C₈ alkenyl group, a substituted or unsubstituted cycloalkyl group, or a substituted or unsubstituted aryl group, provided that at most three X groups are unsubstituted methyl; P⁺ is an ammonium cation or phosphonium cation; and N⁻ is a sulfate anion, halide anion, or hydroxide anion; and
at least one solvent.

2. The polishing composition of claim 1, wherein the at least one polymer removal enhancer comprises a tetraalkylammonium hydroxide of formula (II):
(CH₃(CH₂)ₓ)₄N(OH) (II),
wherein each x, independently, is 0, 1, 2, 3, 4, 5, 6, or 7, provided that the tetraalkylammonium hydroxide of formula (II) is not tetramethylammonium hydroxide.

3. The polishing composition of claim 1, wherein the polymer removal enhancer comprises tetrapropylammonium hydroxide, tetrabutylammonium hydroxide, tetraethylammonium hydroxide, tris(2-hydroxyethyl) methylammonium hydroxide, diallyldimethylammonium chloride, tetrakis(hydroxymethyl) phosphonium sulfate, tetraphenylphosphonium bromide, methyltrioctylammonium chloride, tetrabutylphosphonium hydroxide, hexamethonium hydroxide, benzyldimethylphenylammonium chloride, benzyltriethylammonium hydroxide, tetrahexylammonium hydroxide, or a mixture thereof.

4. The polishing composition of claim 1, wherein the at least one polymer removal enhancer is in an amount of from about 0.01% to about 15% by weight of the composition.

5. The polishing composition of claim 1, wherein the at least one abrasive comprises alumina, silica, titania, ceria, zirconia, co-formed products of alumina, silica, titania, ceria, or zirconia, coated abrasives, surface modified abrasives, or a mixture thereof.

6. The polishing composition of claim 1, wherein the at least one abrasive is in an amount of from about 0.1% to about 50% by weight of the composition.

7. The polishing composition of claim 1, wherein the at least one abrasive has a mean particle size of at least about 100 nm.

8. The polishing composition of claim 1, further comprising at least one surfactant selected from the group consisting of primary fatty amines, secondary fatty amines, ethoxylated amines, ethoxylated ether amines, and cationic surfactants.

9. The polishing composition of claim 8, wherein the at least one surfactant is chemically distinct from the at least one polymer removal enhancer.

10. The polishing composition of claim 8, wherein the at least one surfactant comprises dodecylamine, dicocoalkylamine, tallow amine, bis-(2-hydroxyethyl) isodecyloxypropylamine, poly (5) oxyethylene isodecyloxproplamine, bis-(2-hydroxyethyl) isotridecyloxypropylamine, poly (5) oxyethylene isotridecyloxypropylamine, bis-(2-hydroxyethyl) tallow amine, N-tallow-poly (3) oxyethylene-1,3-diaminopropane, bis-(2-hydroxyethyl) cocoalkyloxypropylamine, poly bis-(2-hydroxyethyl) oxyethylene cocoalkyloxypropylamine, octyltrimethylammonium hydroxide, decyltrimethylammonium hydroxide, dodecyltrimethylammonium hydroxide, tetradecyltrimethylammonium hydroxide, hexadecyltrimethylammonium hydroxide, octadecyltrimethylammonium hydroxide, eicosyltrimethylammonium hydroxide, or a mixture thereof.

11. The polishing composition of claim 8, wherein the at least one surfactant is in an amount of from about 0.0001% to about 10% by weight of the composition.

12. The polishing composition of claim 1, wherein the at least one solvent is in an amount of from about 20% to about 99.9% by weight of the composition.

13. The polishing composition of claim 1, wherein the composition has a pH from about 7.5 to about 14.

14. The polishing composition of claim 1, wherein the composition further comprises at least one nonionic surfactant.

15. The polishing composition of claim 14, wherein the at least one nonionic surfactant is in an amount of from about 0.001% to about 5% by weight of the composition.

16. The polishing composition of claim 1, wherein the composition further comprises at least one azole-containing corrosion inhibitor.

17. The polishing composition of claim 16, wherein the at least one azole-containing corrosion inhibitor is in an amount of from about 0.0001% to about 1% by weight of the composition.

18. A method of polishing a substrate, comprising the steps of:
applying the polishing composition of claim 1 to a surface of a substrate, wherein the surface comprises a polymer; and
bringing a pad into contact with the surface of the substrate and moving the pad in relation to the substrate.

19. The method of claim 18, wherein the polymeric substrate comprises polyimide, acrylonitrile butadiene styrene (ABS), a liquid crystal polymer, polyaryletherketone (PAEK), polyethylene terephthalate (PET), polyphenylene oxide (PPO), polyphenylene sulfide (PPS), polytetrafluoroethylene (PTFE), polybenzobisoxazole (PBO), a benzocyclobutene-based polymer, or an epoxy-based polymer.

20. The method of claim 18, wherein the polymeric substrate is polished at a rate of at least about 200 Å/min.
